(19) United States
(12) Patent Application Publication
(10) Pub. No.: US 2025/0180663 A1
(43) Pub. Date: Jun. 5, 2025

(54) SYSTEM FOR ESTIMATING STATE OF HEALTH OF STORAGE BATTERY, WORK MACHINE, AND METHOD FOR ESTIMATING STATE OF HEALTH OF STORAGE BATTERY

(71) Applicant: KOMATSU LTD., Tokyo (JP)

(72) Inventors: Keiji DEGUCHI, Tokyo (JP); Hayato NAGAKURA, Tokyo (JP); Yuto WATANABE, Tokyo (JP)

(21) Appl. No.: 18/843,469

(22) PCT Filed: Mar. 27, 2023
(86) PCT No.: PCT/JP2023/012182

§ 371 Date: Sep. 3, 2024

(30) Foreign Application Priority Data
Mar. 31, 2022 (JP) 2022-060928

(51) Int. Cl. G01R 31/392; G01R 31/374; G01R 31/382; H01M 10/48; H02J 7/00

(52) U.S. Cl. CPC G01R 31/392; G01R 31/374; G01R 31/382; H01M 10/486; H02J 7/005

(57) ABSTRACT

A system of estimating a state of health of a storage battery includes a controller. The controller is configured to specify a use state of the storage battery, and calculate the state of health of the storage battery in each of a plurality of use states.

### CROSS-REFERENCE TO RELATED APPLICATIONS

This application is a U.S. National stage application of International Application No. PCT/JP2023/012182, filed on Mar. 27, 2023. This U.S. National stage application claims priority under 35 U.S.C. § 119(a) to Japanese Patent Application No. 2022-060928, filed in Japan on Mar. 31, 2022, the entire contents of which are hereby incorporated herein by reference.

The present disclosure relates to a system for estimating a state of health of a storage battery, a work machine, and a method for estimating the state of health of the storage battery.

### BACKGROUND

In a technical field related to a work machine, a work machine using a storage battery as a power source, such as a battery forklift or a battery excavator, has been known. Japanese Patent Application Laid-open No. 2011-064063 discloses an example of a technology of estimating a state of health (SOH) of a storage battery.

### SUMMARY

### Technical Problem

A state of health of a storage battery may change depending on a use state of the storage battery. Thus, when the state of health is estimated without consideration of the use state of the storage battery, estimation accuracy of the state of health may be deteriorated.

An object of the present disclosure is to accurately estimate a state of health of a storage battery.

In order to achieve an aspect of the present invention, a system of estimating a state of health of a storage battery, the system includes a controller, wherein the controller specifies a use state of the storage battery, and calculates the state of health of the storage battery in each of a plurality of the use states.

According to the present disclosure, a state of health of a storage battery is accurately estimated.

### BRIEF DESCRIPTION OF DRAWINGS

FIG. 1 is a perspective view illustrating a work machine according to an embodiment.

FIG. 2 is a view illustrating a part of the work machine according to the embodiment.

FIG. 3 is a block diagram illustrating a charging control system according to the embodiment.

FIG. 4 is a functional block diagram illustrating a state of health estimation system of a storage battery according to the embodiment.

FIG. 5 is a view for describing a parameter stored in a parameter storage unit according to the embodiment.

FIG. 6 is a view for describing a parameter stored in the parameter storage unit according to the embodiment.

FIG. 7 is a view for describing a parameter stored in the parameter storage unit according to the embodiment.

FIG. 8 is a view for describing a parameter stored in the parameter storage unit according to the embodiment.

FIG. 9 is a flowchart illustrating a state of health estimation method of the storage battery according to the embodiment.

FIG. 10 is a view for describing a calculation method of the state of health of the storage battery according to the embodiment.

FIG. 11 is a block diagram illustrating a computer system according to the embodiment.

### DESCRIPTION OF EMBODIMENTS

In the following, embodiments according to the present disclosure will be described with reference to the drawings. However, the present disclosure is not limited to the embodiments. Components of the embodiments described in the following can be arbitrarily combined. Also, there is a case where a part of the components is not used.

### [Work Machine]

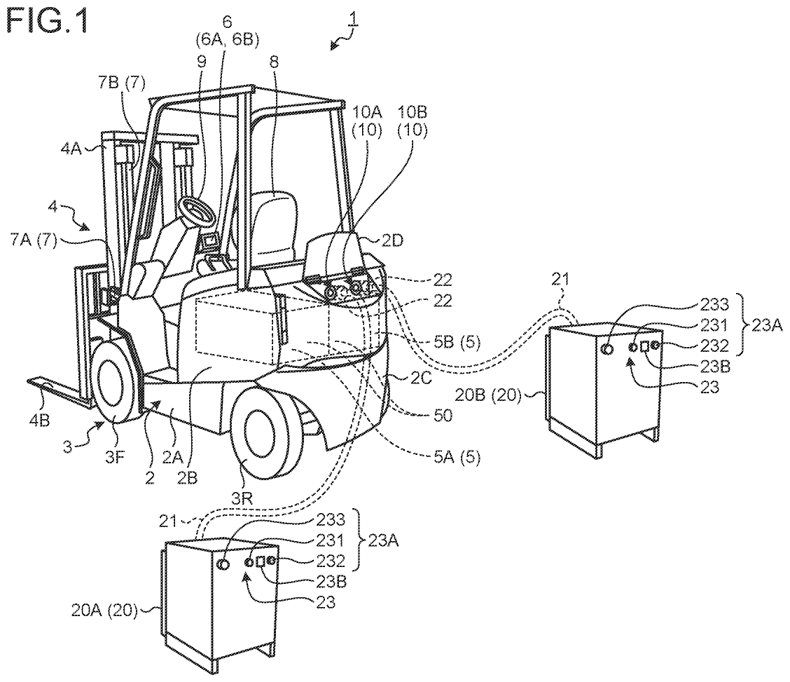

FIG. 1 is a perspective view illustrating a work machine 1 according to an embodiment. In the present embodiment, the work machine 1 is a battery forklift using a storage battery as a power source.

The work machine 1 includes a vehicle body 2, a traveling device 3, working equipment 4, a battery pack 5, an interface device 6, and a connection portion 10.

The vehicle body 2 includes a frame 2A, a housing member 2B, and a counterweight 2C. The housing member 2B is supported by the frame 2A. The housing member 2B is arranged at a rear portion of the vehicle body 2. The housing member 2B has a battery chamber in which the battery pack 5 is arranged. The counterweight 2C is arranged below the housing member 2B.

The traveling device 3 supports the vehicle body 2. The traveling device 3 includes front wheels 3F and rear wheels 3R.

The working equipment 4 is supported by the vehicle body 2. The working equipment 4 includes a mast 4A supported by the vehicle body 2 and a fork 4B supported by the mast 4A. The working equipment 4 is driven by a working equipment cylinder 7. The working equipment cylinder 7 includes atilt cylinder 7A that tilts the mast 4A in a front-rear direction, and a lift cylinder 7B that moves the fork 4B in a vertical direction. When the mast 4A is tilted in the front-rear direction by driving of the tilt cylinder 7A, the fork 4B is tilted in the front-rear direction in a state of being supported by the mast 4A. The fork 4B moves in the vertical direction in a state of being supported by the mast 4A by driving of the lift cylinder 7B.

The battery pack 5 includes a storage battery 50. The battery pack 5 is housed in the housing member 2B. The storage battery 50 is a power source of the work machine 1. Charging and discharging of the storage battery 50 can be repeatedly performed. Examples of the storage battery 50 include a lithium ion battery. In the embodiment, a plurality of the battery packs 5 is mounted on the work machine 1. The two battery packs 5 are provided in the embodiment. The battery packs 5 include a first battery pack 5A and a second battery pack 5B.

The work machine 1 is operated by driving operation by an operator seated on a driver seat 8. The driver seat 8 is supported by the frame 2A. The work machine 1 includes a plurality of operation members operated by the operator. Examples of the operation members include a steering wheel 9. The operator operates the steering wheel 9 by hand and steers the traveling device 3. In addition, although not illustrated, the examples of the operation members include an accelerator pedal, a brake pedal, a working equipment lever, and a forward/reverse lever. The operator operates the accelerator pedal with a foot and drives the traveling device 3. The operator operates the brake pedal with the foot and brakes the traveling device 3. The operator operates the working equipment lever by hand and operates the working equipment 4. The operator operates the forward/reverse lever by hand and switches a traveling direction of the traveling device 3 between a forward movement and a reverse movement.

The interface device 6 is arranged on the vehicle body 2. The interface device 6 is arranged in front of the driver seat 8.

The connection portion 10 is connected to a charging device 20. The connection portion 10 is arranged at a rear portion of the housing member 2B. In the embodiment, a plurality of the connection portions 10 is provided in the work machine 1. In the embodiment, the two connection portions 10 are provided. The connecting portions 10 include a first connection portion 10A and a second connection portion 10B.

The charging device 20 charges the storage battery 50. The charging device 20 is arranged outside the work machine 1. The charging device 20 charges the storage battery 50 from the outside of the work machine 1. In the embodiment, the storage battery 50 can be simultaneously charged by a plurality of the charging devices 20. In the embodiment, the storage battery 50 can be simultaneously charged by the two charging devices 20. The plurality of charging devices 20 is respectively connected to the plurality of connection portions 10. In the embodiment, the charging devices 20 include a first charging device 20A connected to the first connection portion 10A, and a second charging device 20B connected to the second connection portion 10B.

Each of the charging devices 20 is connected to the connection portion 10 via a cable 21 and a plug 22. The connection portion 10 includes an insertion opening into which the plug 22 is inserted. The charging device 20 includes an interface device 23. The interface device 23 includes an operation device 23A operated by the operator, and a display device 23B that displays display data.

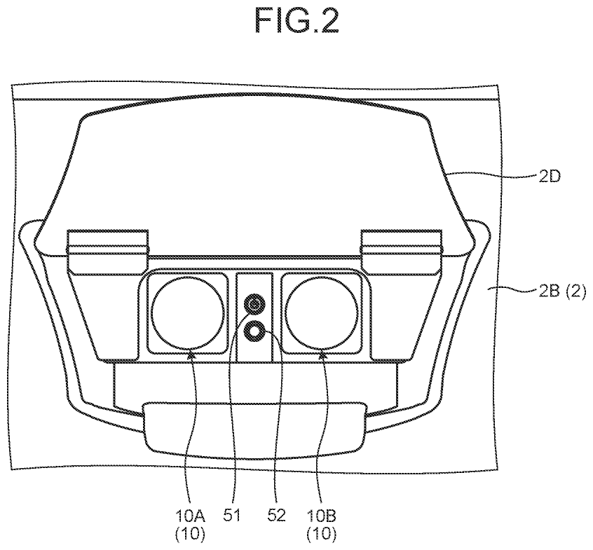

FIG. 2 is a view illustrating a part of the work machine 1 according to the embodiment. As illustrated in FIG. 1 and FIG. 2, the work machine 1 includes a cover 2D that covers the connection portions 10. The first connection portion 10A and the second connection portion 10B are arranged at an interval in a vehicle width direction of the work machine 1. A power switch 51 and an operation lamp 52 are arranged at the rear portion of the vehicle body 2. The power switch 51 and the operation lamp 52 are arranged between the first connection portion 10A and the second connection portion 10B. The power switch 51 is, for example, a momentary switch, but may be another type of operation member. The operation lamp 52 operates on the basis of use states of the storage battery 50. The use states of the storage battery 50 include a charged state, a discharging state, and a standby state. As an example, the operation lamp 52 blinks in a case where the storage battery 50 is in the charged state, and the operation lamp 52 is turned on in a case where the storage battery 50 is in the discharging state.

### [Charging Control System]

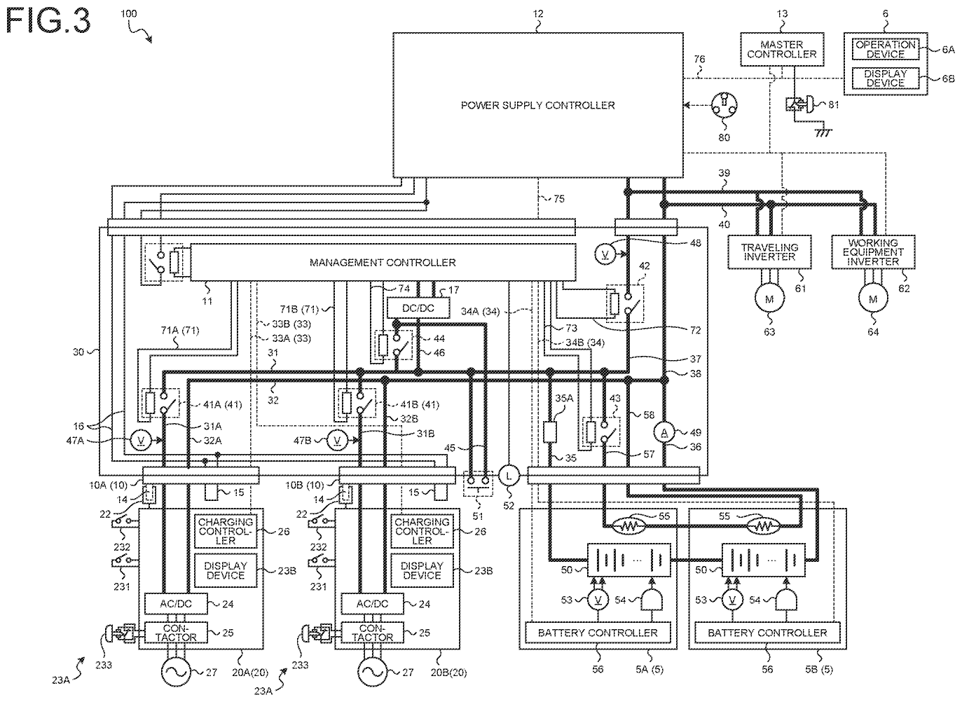

FIG. 3 is a block diagram illustrating a charging control system 100 according to the embodiment. The charging control system 100 includes the battery packs 5, the charging devices 20, the connection portions 10, a management controller 11, a control circuit 30, a power supply controller 12, a master controller 13, and the interface device 6.

Each of the battery packs 5 includes the storage battery 50, a voltage sensor 53 that detects a voltage of the storage battery 50, a temperature sensor 54 that detects a temperature of the storage battery 50, a heater 55 that heats the storage battery 50, and a battery controller 56.

Each of the charging devices 20 includes the operation device 23A, the display device 23B, an AC/DC conversion module 24 connected to a commercial power supply 27, a contactor 25 arranged between the commercial power supply 27 and the AC/DC conversion module 24, and a charging controller 26.

The operation device 23A includes a charging start operation unit 231 that causes the charging device 20 to perform charging operation, a charging stop operation unit 232 that causes the charging device 20 to perform charging stop operation, and an emergency stop operation unit 233 that causes the charging device 20 to perform emergency stop operation. The charging start operation unit 231 and the charging stop operation unit 232 are, for example, toggle switches, rocker switches, or push button switches, but may be other types of operation members. The emergency stop operation unit 233 is, for example, a push button switch, but may be another type of operation member.

Each of the connection portions 10 includes a lock sensor 14 that detects that the plug 22 and the connection portion 10 are locked. In addition, the connection portion 10 is provided with an energization line 15 that is energized when the plug 22 of the charging device 20 and the connection portion 10 are connected. The energization line 15 is connected to the power supply controller 12 via a detection line 16. The power supply controller 12 can determine whether the plug 22 of the charging device 20 and the connection portion 10 are connected on the basis of a detection signal of the lock sensor 14 or an energization state of the energization line 15 which state is acquired via the detection line 16.

The control circuit 30 includes a positive electrode line 31 connected to a positive electrode of the charging device 20 via the connection portion 10, a negative electrode line 32 connected to a negative electrode of the charging device 20 via the connection portion 10, a signal line 33 that connects the management controller 11 and the charging controller 26 via the connection portion 10, and a signal line 34 that connects the management controller 11 and the battery controller 56.

The signal line 33 includes a signal line 33A that connects the management controller 11 and the charging controller 26 of the first charging device 20A, and a signal line 33B that connects the management controller 11 and the charging controller 26 of the second charging device 20B.

The signal line 34 includes a signal line 34A that connects the management controller 11 and the battery controller 56 of the first battery pack 5A, and a signal line 34B that connects the management controller 11 and the battery controller 56 of the second battery pack 5B.

The first charging device 20A and the second charging device 20B are connected in parallel to the positive electrode line 31. The first charging device 20A and the second charging device 20B are connected in parallel to the negative electrode line 32. The first charging device 20A and the positive electrode line 31 are connected via a positive electrode line 31A. The second charging device 20B and the positive electrode line 31 are connected via a positive electrode line 31B. The first charging device 20A and the negative electrode line 32 are connected via a negative electrode line 32A. The second charging device 20B and the negative electrode line 32 are connected via a negative electrode line 32B.

The storage battery 50 of the first battery pack 5A and the storage battery 50 of the second battery pack 5B are connected in series. The positive electrode line 31 is connected to a positive electrode of the storage battery 50 of the first battery pack 5A via a positive electrode line 35. The negative electrode line 32 is connected to a negative electrode of the storage battery 50 of the second battery pack 5B via a negative electrode line 36. A fuse 35A is arranged on the positive electrode line 35.

The heater 55 of the first battery pack 5A and the heater 55 of the second battery pack 5B are connected in series. The positive electrode line 31 is connected to a positive electrode of the heater 55 of the first battery pack 5A via a positive electrode line 57. The negative electrode line 32 is connected to a negative electrode of the heater 55 of the second battery pack 5B via a negative electrode line 58.

The positive electrode line 35 is connected to each of a traveling inverter 61 and a working equipment inverter 62 via a positive electrode line 37 and a positive electrode line 39. The negative electrode line 36 is connected to each of the traveling inverter 61 and the working equipment inverter 62 via a negative electrode line 38 and a negative electrode line 40. The traveling inverter 61 and the working equipment inverter 62 are connected in parallel to the positive electrode line 39. The traveling inverter 61 and the working equipment inverter 62 are connected in parallel to the negative electrode line 40.

In addition, the control circuit 30 includes a charge contactor 41 arranged on the positive electrode line 31. When the charge contactor 41 is turned on, the charging device 20 and the storage battery 50 are connected via the positive electrode line 31 and the positive electrode line 35, and the storage battery 50 is charged by the charging device 20. When the charge contactor 41 is turned off, the charging device 20 and the storage battery 50 are separated, and the storage battery 50 is not charged.

In the embodiment, the charge contactor 41 includes a charge contactor 41A that switches connection and separation between the first charging device 20A and the storage battery 50, and a charge contactor 41B that switches connection and separation between the second charging device 20B and the storage battery 50. The charge contactor 41A is arranged on the positive electrode line 31A. The charge contactor 41B is arranged in the positive electrode line 31B. When the charge contactor 41A is turned on, the first charging device 20A and the storage battery 50 are connected, and the storage battery 50 is charged by the first charging device 20A. When the charge contactor 41A is turned off, the first charging device 20A and the storage battery 50 are separated, and the storage battery 50 is not charged by the first charging device 20A. When the charge contactor 41B is turned on, the second charging device 20B and the storage battery 50 are connected, and the storage battery 50 is charged by the second charging device 20B. When the charge contactor 41B is turned off, the second charging device 20B and the storage battery 50 are separated, and the storage battery 50 is not charged by the second charging device 20B.

The management controller 11 is connected to the charge contactor 41 via a control line 71. The control line 71 includes a control line 71A that connects the management controller 11 and the charge contactor 41A, and a control line 71B that connects the management controller 11 and the charge contactor 41B. The management controller 11 controls the charge contactor 41 via the control line 71.

In addition, the control circuit 30 also includes a discharge contactor 42 arranged on the positive electrode line 37. When the discharge contactor 42 is turned on, the storage battery 50 is connected to each of the traveling inverter 61 and the working equipment inverter 62 via the positive electrode line 37 and the positive electrode line 39, and electric power is supplied to each of the traveling inverter 61 and the working equipment inverter 62 by discharging from the storage battery 50. When the discharge contactor 42 is turned off, the storage battery 50 is separated from each of the traveling inverter 61 and the working equipment inverter 62, and electric power is not supplied from the storage battery 50 to each of the traveling inverter 61 and the working equipment inverter 62.

The management controller 11 is connected to the discharge contactor 42 via a control line 72. The management controller 11 controls the discharge contactor 42 via the control line 72.

In addition, the control circuit 30 includes a heater contactor 43 arranged on the positive electrode line 57. When the heater contactor 43 is turned on, at least one of the charging device 20 or the storage battery 50, and the heater 55 are connected via the positive electrode line 57, and electric power is supplied to the heater 55. When the heater contactor 43 is turned off, the charging device 20, the storage battery 50, and the heater 55 are separated, and electric power is not supplied to the heater 55.

The management controller 11 is connected to the heater contactor 43 via a control line 73. The management controller 11 controls the heater contactor 43 via the control line 73.

In the embodiment, a detection signal of the voltage sensor 53 is transmitted from the battery controller 56 to the management controller 11 via the signal line 34. A detection signal of the temperature sensor 54 is transmitted from the battery controller 56 to the management controller 11 via the signal line 34.

In the storage battery 50, a recommended voltage range and a recommended temperature range of when the storage battery 50 is discharged are set. In a case where the voltage of the storage battery 50 is not within the recommended temperature range or a case where the temperature of the storage battery 50 is not within the recommended temperature range, the management controller 11 controls the discharge contactor 42 in such a manner that the storage battery 50 does not discharge. That is, the management controller 11 turns off the discharge contactor 42 in a case of determining that the voltage of the storage battery 50 is not in the recommended temperature range on the basis of the detection signal of the voltage sensor 53 or in a case of determining that the temperature of the storage battery 50 is not in the recommended temperature range on the basis of the detection signal of the temperature sensor 54. In a case of determining that the voltage of the storage battery 50 is in the recommended temperature range and the temperature of the storage battery 50 is in the recommended temperature range, the management controller 11 turns on the discharge contactor 42.

In addition, in the storage battery 50, a recommended temperature range of when the storage battery 50 is charged is set. In a case of determining that the temperature of the storage battery 50 is equal to or lower than the recommended temperature range on the basis of the detection signal of the temperature sensor 54, the management controller 11 controls the heater contactor 43 in such a manner that the electric power is supplied to the heater 55. When the electric power is supplied to the heater 55, the storage battery 50 is heated by the heater 55. When the storage battery 50 is heated by the heater 55, the temperature of the storage battery 50 rises to the recommended temperature range.

In addition, the control circuit 30 includes a power supply circuit 17 of the management controller 11, and a self-holding relay 44 of the management controller 11. The positive electrode line 31 is connected to the power supply circuit 17 via the power switch 51 and a positive electrode line 45. In addition, the positive electrode line 31 is connected to the power supply circuit 17 via the self-holding relay 44. The negative electrode line 32 is connected to the power supply circuit 17 via a negative electrode line 46. As described above, the power switch 51 is arranged at the rear portion of the vehicle body 2. The operator can operate the power switch 51. When the power switch 51 is turned on, electric power is supplied to the power supply circuit 17, and the management controller 11 is activated. When the power switch 51 is turned off, electric power supply to the power supply circuit 17 is cut off, and the management controller 11 is stopped.

The management controller 11 is connected to the self-holding relay 44 via a control line 74. The management controller 11 controls the self-holding relay 44 via the control line 74. The management controller 11 controls the self-holding relay 44 in such a manner that the supply of the electric power to the power supply circuit 17 is cut off when capacity of the storage battery 50 becomes equal to or lower than a predetermined threshold.

In addition, the control circuit 30 includes a voltage sensor 47A that detects a voltage of the positive electrode line 31A, a voltage sensor 47B that detects a voltage of the positive electrode line 31B, a voltage sensor 48 that detects a voltage of the positive electrode line 39, and a current sensor 49 that detects a current of the negative electrode line 36.

On the basis of a detection signal of the voltage sensor 47A, the management controller 11 determines whether a malfunction of the charge contactor 41A is generated. In a case where the charge contactor 41A is turned off, the voltage detected by the voltage sensor 47A decreases. In a case where the voltage detected by the voltage sensor 47A is high although the control signal to turn off the charge contactor 41A is output, the management controller 11 can determine that malfunction of the charge contactor 41A is generated.

Similarly, the management controller 11 can determine whether a malfunction of the charge contactor 41B is generated on the basis of a detection signal of the voltage sensor 47B. The management controller 11 can determine whether a malfunction of the discharge contactor 42 is generated on the basis of a detection signal of the voltage sensor 48.

The traveling inverter 61 converts a direct current from the positive electrode line 39 into a three-phase alternating current and supplies the three-phase alternating current to a traveling motor 63. The traveling motor 63 is driven on the basis of the three-phase alternating current supplied from the traveling inverter 61. The traveling motor 63 causes the traveling device 3 to operate. In the embodiment, the traveling motor 63 generates power that rotates at least one of the front wheels 3F or the rear wheels 3R.

The working equipment inverter 62 converts the direct current from the positive electrode line 39 into a three-phase alternating current, and supplies the three-phase alternating current to a working equipment motor 64. The working equipment motor 64 is driven on the basis of the three-phase alternating current supplied from the working equipment inverter 62. The working equipment motor 64 causes the working equipment 4 to operate. In the embodiment, the working equipment motor 64 generates power that drives a hydraulic pump (not illustrated). A hydraulic oil discharged from the hydraulic pump is supplied to the working equipment cylinder 7. When the hydraulic oil is supplied to the working equipment cylinder 7, the working equipment 4 operates.

The power supply controller 12 is connected to the management controller 11 via a communication line 75. The power supply controller 12 is connected to the master controller 13 via a communication line 76. The power supply controller 12 is a host controller of the management controller 11. The management controller 11 operates on the basis of a control signal from the power supply controller 12.

The master controller 13 controls the traveling inverter 61 and the working equipment inverter 62 on the basis of the operation of the operation member described above. The master controller 13 controls the traveling inverter 61 on the basis of, for example, the operation on at least one of the accelerator pedal or the brake pedal. The master controller 13 controls the working equipment inverter 62 on the basis of operation on a working lever.

The work machine 1 includes an interface device 6, a key switch 80, and an emergency stop operation unit 81. The interface device 6 includes an operation device 6A operated by the operator, and a display device 6B that displays display data. The operation device 6A includes a charging start operation unit that causes the charging device 20 to perform charging operation, and a charging stop operation unit that causes the charging device 20 to perform charging stop operation. The operation device 6A is, for example, a computer keyboard, a push button switch, or a touch panel arranged on a display screen of the display device 6B. The display device 6B is, for example, a flat panel display such as a liquid crystal display or an organic EL display.

The key switch 80 is arranged on the vehicle body 2. The key switch 80 is operated by, for example, the operator seated on the driver seat 8. When the key switch 80 is turned on, the work machine 1 becomes an operable state.

The emergency stop operation unit 81 is arranged in the vehicle body 2. The emergency stop operation unit 81 is operated by, for example, the operator seated on the driver seat 8. The emergency stop operation unit 81 is, for example, a push button switch, but may be another type of operation member.

### [State of Health Estimation System]

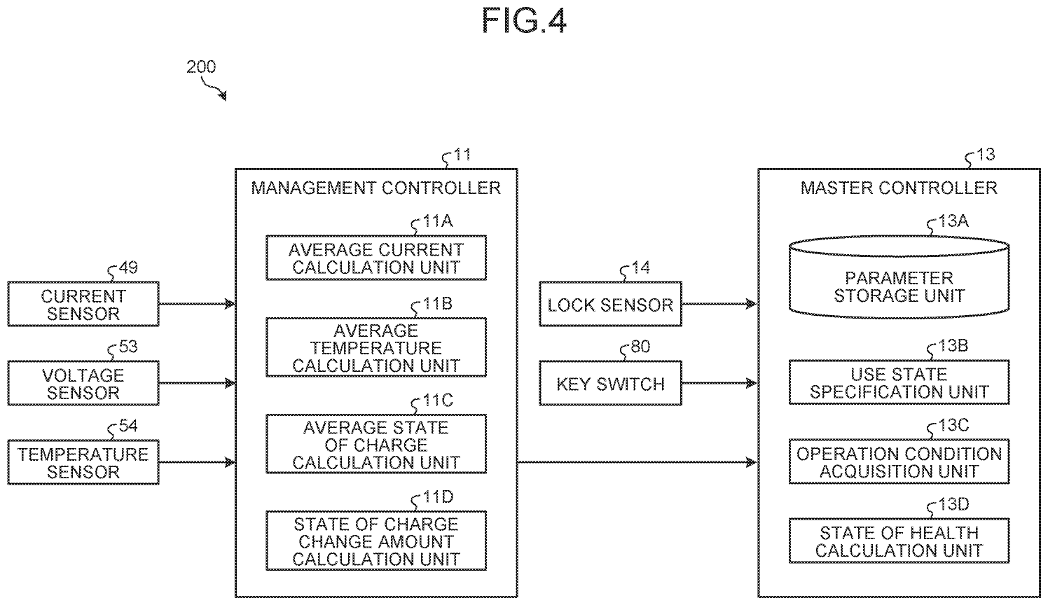

FIG. 4 is a functional block diagram illustrating a state of health estimation system 200 of the storage battery 50 according to the embodiment. The state of health estimation system 200 estimates a state of health (SOH) of the storage battery 50 mounted on the work machine 1. The storage battery 50 is used in a plurality of use states different from each other. The use states of the storage battery 50 include a charged state of the storage battery 50, a discharging state of the storage battery 50, and a suspended state of the storage battery 50. The charged state of the storage battery 50 refers to a state in which the storage battery 50 is charged. The discharging state of the storage battery 50 refers to a state in which the storage battery 50 discharges. The suspended state of the storage battery 50 refers to a state in which the storage battery 50 is not charged and does not discharge. Note that in the suspended state of the storage battery 50, the storage battery 50 may naturally discharge.

The state of health of the storage battery 50 may change depending on the use states of the storage battery 50. In the embodiment, the state of health estimation system 200 estimates the state of health of the storage battery 50 in each of the plurality of use states.

The state of health estimation system 200 includes the management controller 11, the master controller 13, the current sensor 49, the voltage sensor 53, the temperature sensor 54, the lock sensor 14, and the key switch 80.

As illustrated in FIG. 3, the current sensor 49 is arranged on the negative electrode line 36. The current sensor 49 detects the current of the negative electrode line 36 in each of the plurality of use states of the storage battery 50. That is, the current sensor 49 detects the current in the negative electrode line 36 in each of the charged state of the storage battery 50, the discharging state of the storage battery 50, and the suspended state of the storage battery 50. In the charged state of the storage battery 50, the current sensor 49 detects the current charged in the storage battery 50. In the discharging state of the storage battery 50, the current sensor 49 detects the current discharged from the storage battery 50. In the suspended state of the storage battery 50, the current sensor 49 detects the current of the negative electrode line 36. In the suspended state of the storage battery 50, the current of the negative electrode line 36 may be detected due to the natural discharge of the storage battery 50. In the following description, the current of the negative electrode line 36 is appropriately referred to as the current of the storage battery 50.

As illustrated in FIG. 3, the voltage sensor 53 is arranged in the battery pack 5. The voltage sensor 53 detects the voltage of the storage battery 50 in each of the plurality of use states of the storage battery 50. That is, the voltage sensor 53 detects the voltage of the storage battery 50 in each of the charged state of the storage battery 50, the discharging state of the storage battery 50, and the suspended state of the storage battery 50.

As illustrated in FIG. 3, the temperature sensor 54 is arranged in the battery pack 5. The temperature sensor 54 detects the temperature of the storage battery 50 in each of the plurality of use states of the storage battery 50. That is, the temperature sensor 54 detects the temperature of the storage battery 50 in each of the charged state of the storage battery 50, the discharging state of the storage battery 50, and the suspended state of the storage battery 50.

The lock sensor 14 detects that the plug 22 and the connection portion 10 are locked. The lock sensor 14 can detect whether the charging device 20 and the connection portion 10 of the work machine 1 are connected.

The key switch 80 is operated by the operator to activate at least the charging control system 100 and the master controller 13. The charging control system 100 is activated by the operation on the power switch 51, and the key switch 80 is keyed on, whereby the charging control system 100 and the master controller 13 are activated. When the charging control system 100 and the master controller 13 are activated, the work machine 1 becomes operable.

The management controller 11 calculates an operation condition of the storage battery 50. The operation condition of the storage battery 50 includes an average current, an average temperature, an average state of charge (average SOC), and a state of charge change amount (ASOC) of the storage battery 50 in use time h in each of the plurality of use states. The management controller 11 includes a timer that measures the use time h.

The use time h of the storage battery 50 refers to a time during which each of the plurality of use states of the storage battery 50 is continued. In the embodiment, the use time h of the storage battery 50 include charged time indicating the use time of when the use state of the storage battery 50 is the charged state, discharging time indicating the use time of when the use state of the storage battery 50 is the discharging state, and suspended time indicating the use time of when the use state of the storage battery 50 is the suspended state.

The management controller 11 includes an average current calculation unit 11A, an average temperature calculation unit 11B, an average state of charge calculation unit 11C, and a state of charge change amount calculation unit 11D.

The average current calculation unit 11A calculates an average current indicating an average value of the current of the storage battery 50 during the use time h of the storage battery 50. The current of the storage battery 50 is detected by the current sensor 49. The average current calculation unit 11A calculates the average current of the storage battery 50 during the use time h on the basis of the detection signal of the current sensor 49 and a measurement result of the timer. In the embodiment, the average current calculation unit 11A calculates each of the average current in the charged time, the average current in the discharging time, and the average current in the suspended time.

The average temperature calculation unit 11B calculates an average temperature indicating an average value of the temperature of the storage battery 50 during the use time h of the storage battery 50. The temperature of the storage battery 50 is detected by the temperature sensor 54. The average temperature calculation unit 11B calculates the average temperature of the storage battery 50 during the use time h on the basis of the detection signal of the temperature sensor 54 and the measurement result of the timer. In the embodiment, the average temperature calculation unit 11B calculates each of the average temperature in the charged time, the average temperature in the discharging time, and the average temperature in the suspended time.

The average state of charge calculation unit 11C calculates an average state of charge (average SOC) indicating an average value of the state of charge (SOC) of the storage battery 50 during the use time h of the storage battery 50. The average state of charge calculation unit 11C can calculate the SOC on the basis of the voltage of the storage battery 50 which voltage is detected by the voltage sensor 53 and the current of the storage battery 50 which current is detected by the current sensor 49. The average state of charge calculation unit 11C calculates the average SOC of the storage battery 50 during the use time h on the basis of the detection signal of the voltage sensor 53, the detection signal of the current sensor 49, and the measurement result of the timer. In the embodiment, the average state of charge calculation unit 11C calculates each of the average SOC in the charged time, the average SOC in the discharging time, and the average SOC in the suspended time.

The state of charge change amount calculation unit 11D calculates the state of charge change amount (ΔSOC) indicating the change amount in the state of charge (SOC) during the use time h of the storage battery 50. The state of charge change amount calculation unit 11D calculates ΔSOC of the storage battery 50 on the basis of the detection signal of the voltage sensor 53, the detection signal of the current sensor 49, and the measurement result of the timer. In the embodiment, the state of charge change amount calculation unit 11D calculates each of ΔSOC in the charged time, ΔSOC in the discharging time, and ΔSOC in the suspended time.

The master controller 13 includes a parameter storage unit 13A, a use state specification unit 13B, an operation condition acquisition unit 13C, and a state of health calculation unit 13D.

The parameter storage unit 13A stores parameters used when a deterioration rate influence degree of the storage battery 50 in each of the plurality of use states is calculated. The parameters are derived in advance on the basis of a load of the storage battery 50 and actual measurement data of the state of health of the storage battery 50, and are stored in the parameter storage unit 13A. The parameters indicate characteristic values related to the deterioration rate of the storage battery 50.

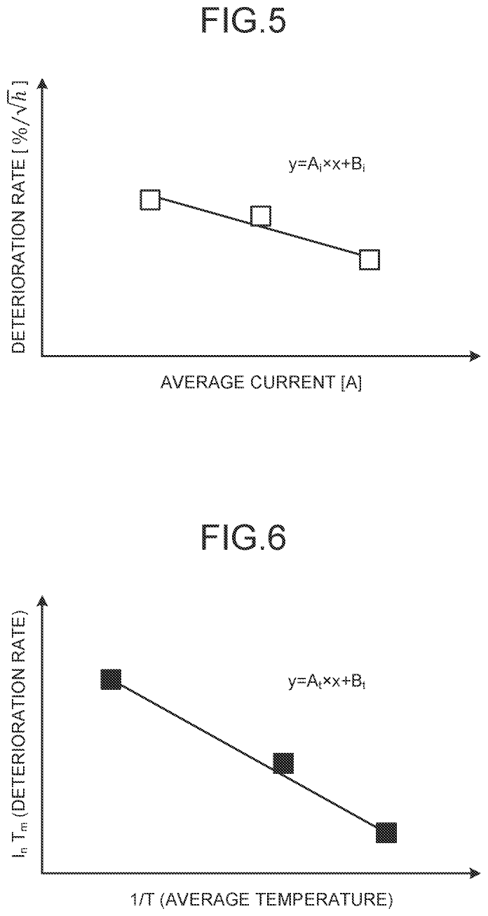

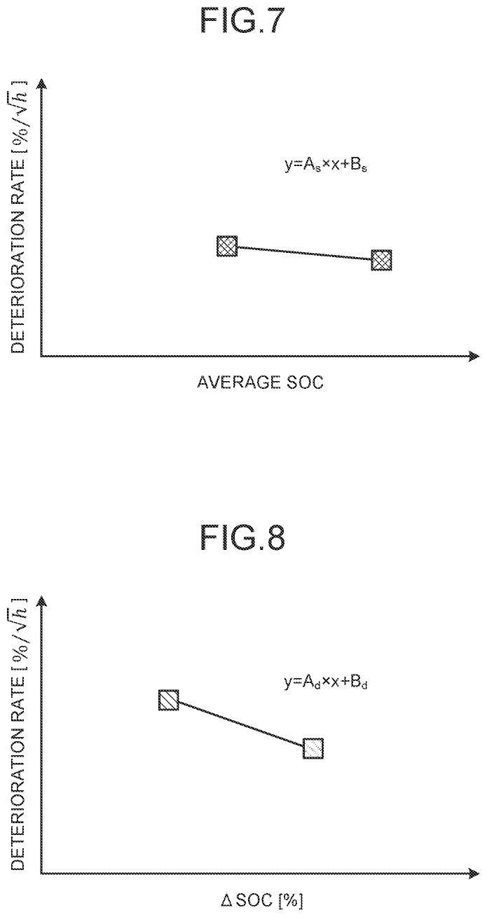

FIG. 5, FIG. 6, FIG. 7, and FIG. 8 are views for describing the parameters stored in the parameter storage unit 13A according to the embodiment. The parameter storage unit 13A stores correlation data indicating a relationship between the operation condition of the storage battery 50 and the deterioration rate of the storage battery 50. As illustrated in FIG. 5, the parameter storage unit 13A stores correlation data indicating a relationship between the average current of the storage battery 50 and the deterioration rate of the storage battery 50. The parameter storage unit 13A stores correlation data indicating a relationship between the average temperature of the storage battery 50 and the deterioration rate of the storage battery 50. In the present embodiment, the correlation data indicating the relationship between the average temperature of the storage battery 50 and the deterioration rate of the storage battery 50 is derived from the Arrhenius law in which a horizontal axis is a reciprocal of the temperature and a vertical axis is a logarithm of the deterioration rate as illustrated in FIG. 6. As illustrated in FIG. 7, the parameter storage unit 13A stores correlation data indicating a relationship between the average SOC of the storage battery 50 and the deterioration rate of the storage battery 50. As illustrated in FIG. 8, the parameter storage unit 13A stores correlation data indicating a relationship between ΔSOC of the storage battery 50 and the deterioration rate of the storage battery 50. The correlation data illustrated in each of FIG. 5, FIG. 6, FIG. 7, and FIG. 8 is actual measurement data derived from a preliminary experiment. Note that the correlation data may be derived by simulation.

As illustrated in FIG. 5, the deterioration rate becomes higher as the average current is higher. In the graph illustrated in FIG. 5, in a case where a horizontal axis x represents the average current and a vertical axis y represents the deterioration rate, a proportional relationship represented by a linear function [y=Ai×x+Bi] is established between the average current and the deterioration rate when the measurement data is approximated to first order.

As illustrated in FIG. 6, the deterioration rate becomes higher as the average temperature is higher. In the graph illustrated in FIG. 6, in a case where a horizontal axis x represents the average temperature and a vertical axis y represents the deterioration rate, a proportional relationship represented by a linear function [y=At ×x+Bt] is established between the average temperature and the deterioration rate when the measurement data is approximated to first order.

As illustrated in FIG. 7, the deterioration rate becomes higher as the average SOC is higher. In the graph illustrated in FIG. 7, in a case where a horizontal axis x represents the average SOC and a vertical axis y represents the deterioration rate, a proportional relationship represented by a linear function [y=As ×x+Bs] is established between the average SOC and the deterioration rate when the measurement data is approximated to first order.

As illustrated in FIG. 8, the deterioration rate becomes higher as ΔSOC is higher. In the graph illustrated in FIG. 8, in a case where a horizontal axis x represents ΔSOC and a vertical axis y represents the deterioration rate, a proportional relationship represented by a linear function [y=Ad×x+Bd] is established between ΔSOC and the deterioration rate when the measurement data is approximated to first order.

The parameters are derived from the correlation data represented by the linear function in a manner illustrated in each of FIG. 5 to FIG. 8. In the embodiment, the parameters include a slope Ai and an intercept Bi of the linear function indicating the relationship between the average current and the deterioration rate, a slope At and an intercept Bt of the linear function indicating the relationship between the average temperature and the deterioration rate, a slope As and an intercept Bs of the linear function indicating the relationship between the average SOC and the deterioration rate, and a slope Ad and an intercept Bd of the linear function indicating the relationship between ΔSOC and the deterioration rate. The parameter storage unit 13A stores the slope Ai, the intercept Bi, the slope At, the intercept Bt, the slope As, the intercept Bs, the slope Ad, and the intercept Bd.

The use state specification unit 13 specifies the use states of the storage battery 50 mounted on the work machine 1. As described above, the use states of the storage battery 50 include the charged state of the storage battery 50, the discharging state of the storage battery 50, and the suspended state of the storage battery 50. In the embodiment, the use state specification unit 13B specifies the use state of the storage battery 50 on the basis of an operation signal of the key switch 80 and the detection signal of the lock sensor 14. For example, in a case where it is determined that the plug 22 is connected to the connection portion 10 on the basis of the detection signal of the lock sensor 14, the use state specification unit 13B specifies that the storage battery 50 is in the charged state. In a case where it is determined that the key switch 80 is keyed on on the basis of the operation signal of the key switch 80 and it is determined that the plug 22 is not connected to the connection portion 10 on the basis of the detection signal of the lock sensor 14, the use state specification unit 13B specifies that the storage battery 50 is in the discharging state. In a case where it is determined that the key switch 80 is keyed off on the basis of the operation signal of the key switch 80 and it is determined that the plug 22 is not connected to the connection portion 10 on the basis of the detection signal of the lock sensor 14, the use state specification unit 13B specifies that the storage battery 50 is in the suspended state.

The operation condition acquisition unit 13 acquires an operation condition of the storage battery 50. As described above, the operation condition of the storage battery 50 includes the average current, the average temperature, the average SOC, and ΔSOC of the storage battery 50 in the use time h in each of the plurality of use states. The operation condition acquisition unit 13C acquires the average current of the storage battery 50 from the average current calculation unit 11A. The operation condition acquisition unit 13C acquires the average temperature of the storage battery 50 from the average temperature calculation unit 11B. The operation condition acquisition unit 13C acquires the average SOC of the storage battery 50 from the average state of charge calculation unit 11C. The operation condition acquisition unit 13C acquires ΔSOC of the storage battery 50 from the state of charge change amount calculation unit 11D.

The state of health calculation unit 13D calculates the state of health of the storage battery 50 in each of the plurality of use states of the storage battery 50. The state of health calculation unit 13D calculates the state of health of the storage battery 50 in the use state specified by the use state specification unit 13B. In a case where it is specified that the use state of the storage battery 50 is the charged state, the state of health calculation unit 13D calculates the state of health of the storage battery 50 in the charged state. In a case where it is specified that the use state of the storage battery 50 is the discharging state, the state of health calculation unit 13D calculates the state of health of the storage battery 50 in the discharging state. In a case where it is specified that the use state of the storage battery 50 is the suspended state, the state of health calculation unit 13D calculates the state of health of the storage battery 50 in the suspended state.

The state of health calculation unit 13D calculates the state of health of the storage battery 50 in the use state specified by the use state specification unit 13B on the basis of the parameters stored in the parameter storage unit 13A and the operation condition of the storage battery 50 which condition is acquired by the operation condition acquisition unit 13C. In a case where it is specified that the use state of the storage battery 50 is the charged state, the state of health calculation unit 13D calculates the state of health of the storage battery 50 in the charged state on the basis of the parameters and the operation condition. In a case where it is specified that the use state of the storage battery 50 is the discharging state, the state of health calculation unit 13D calculates the state of health of the storage battery 50 in the discharging state on the basis of the parameters and the operation condition. In a case where it is specified that the use state of the storage battery 50 is the suspended state, the state of health calculation unit 13D calculates the state of health of the storage battery 50 in the suspended state on the basis of the parameters and the operation condition.

### [State of Health Estimation Method]

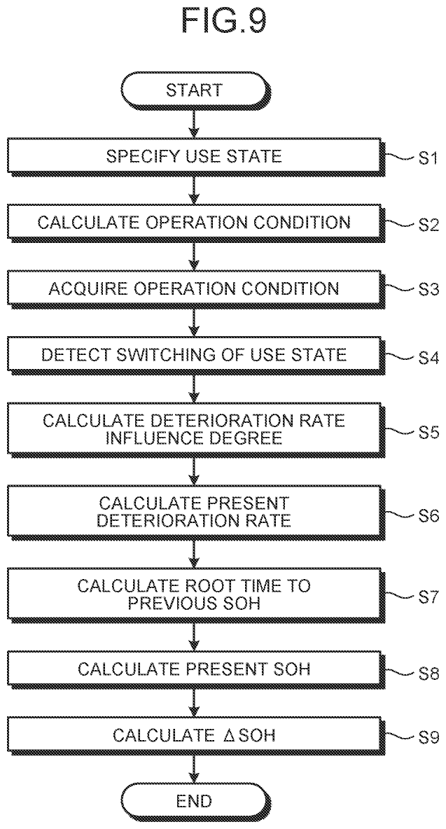

FIG. 9 is a flowchart illustrating a state of health estimation method of the storage battery 50 according to the embodiment. In the following description, the state of health of the storage battery 50 is appropriately referred to as an SOH.

The use state specification unit 13 specifies a present use state of the storage battery 50 on the basis of the operation signal of the key switch 80 and the detection signal of the lock sensor 14 (Step S1).

The management controller 11 calculates a present operation condition of the storage battery 50 (Step S2). That is, the average current calculation unit 11A calculates a present average current of the storage battery 50. The average temperature calculation unit 11B calculates a present average temperature of the storage battery 50. The average state of charge calculation unit 11C calculates a present average SOC of the storage battery 50. The state of charge change amount calculation unit 11D calculates a present ΔSOC of the storage battery 50.

The operation condition acquisition unit 13C acquires the present operation condition of the storage battery 50 from the management controller 11 (Step S3). That is, the operation condition acquisition unit 13C acquires the present average current, average temperature, average SOC, and ΔSOC of the storage battery 50 from the management controller 11.

The use state specification unit 13B detects switching of the use states of the storage battery 50 (Step S4). In the embodiment, the switching of the use states of the storage battery 50 includes at least one of switching from the charged state to the discharging state, switching from the discharging state to the suspended state, switching from the suspended state to the charged state, switching from the charged state to the suspended state, switching from the suspended state to the discharging state, or switching from the discharging state to the charged state.

In a case where the switching of the use states of the storage battery 50 is detected by the use state specification unit 13B in Step S4, the state of health calculation unit 13D starts calculating the SOH of the storage battery 50 in the use state specified by the use state specification unit 13B in Step S4 on the basis of the parameters stored in the parameter storage unit 13A and the operation condition of the storage battery 50 which condition is acquired by the operation condition acquisition unit 13C in Step S3.

First, the state of health calculation unit 13D calculates the deterioration rate influence degree of the storage battery 50 on the basis of the parameters stored in the parameter storage unit 13A and the operation condition of the storage battery 50 which condition is acquired by the operation condition acquisition unit 13C (Step S5). The deterioration rate influence degree means a deterioration rate obtained by assignment of the operation condition acquired by the operation condition acquisition unit 13C into correlation data represented by a linear function.

The state of health calculation unit 13D calculates the deterioration rate influence degree related to the average current on the basis of the slope Ai and the intercept Bi that are the parameters and the average current that is the operation condition. In a case where the average current is denoted by Ia and the deterioration rate influence degree related to the average current is denoted by Im, the deterioration rate influence degree Im related to the average current Ia is calculated on the basis of the following expression (1). As expressed in the expression (1), the deterioration rate influence degree Im is a deterioration rate obtained by assignment of the average current Ia into the linear function [y=Ai×x+Bi] indicating the relationship between the average current and the deterioration rate.

$$\text{?} [ \% / \sqrt{h} ] = {A}_{i} \times \text{?} + {B}_{i} \qquad ( 1 )$$

$$\text{?} \text{indicates text missing or illegible when filed}$$

The state of health calculation unit 13 calculates the deterioration rate influence degree related to the average temperature on the basis of the slope At and the intercept Bt that are the parameters and the average temperature that is the operation condition. In a case where the average temperature is Ta and the deterioration rate influence degree related to the average temperature is Tm, the deterioration rate influence degree Tm related to the average temperature Ta is calculated on the basis of the following expression (2). As expressed in the expression (2), the deterioration rate influence degree Tm is a deterioration rate obtained by assignment of the average temperature Ta into the linear function [y=At ×x+Bt] indicating the relationship between the average temperature and the deterioration rate.

$${T}_{m} [ \% / \sqrt{h} ] = {B}_{t exp} ( - {A}_{t} \times \frac{1}{{T}_{a}} ) \qquad ( 2 )$$

The state of health calculation unit 13D calculates the deterioration rate influence degree related to the average SOC on the basis of the slope As and the intercept Bs that are the parameters and the average SOC that is the operation condition. In a case where the average SOC is Sa and the deterioration rate influence degree related to the average SOC is Sm, the deterioration rate influence degree Sm related to the average SOCSa is calculated on the basis of the following expression (3). As expressed in the expression (3), the deterioration rate influence degree Sm is a deterioration rate obtained by assignment of the average SOCSa into the linear function [y=As ×x+Bs] indicating the relationship between the average SOC and the deterioration rate.

$${S}_{m} [ \% / \sqrt{h} ] = \text{?} \times \text{?} + \text{?} \qquad ( 3 )$$

$$\text{?} \text{indicates text missing or illegible when filed}$$

The state of health calculation unit 13D calculates the deterioration rate influence degree related to ΔSOC on the basis of the slope Ad and the intercept Bd that are the parameters and ΔSOC that is the operation condition. In a case where ΔSOC is Da and the deterioration rate influence degree related to ΔSOC is Dm, the deterioration rate influence degree Dm related to ΔSOCDa is calculated on the basis of the following expression (4). As expressed in the expression (4), the deterioration rate influence degree Dm is a deterioration rate obtained by assignment of ΔSOCDa into the linear function [y=Ad×x+Bd] indicating the relationship between ΔSOC and the deterioration rate.

$${D}_{m} [ \% / \sqrt{h} ] = {A}_{d} \times {D}_{a} + {B}_{d} \qquad ( 4 )$$

After calculating the deterioration rate influence degree Im, the deterioration rate influence degree Tm, the deterioration rate influence degree Sm, and the deterioration rate influence degree Dm, the state of health calculation unit 13D calculates the present deterioration rate Vn indicating the deterioration rate of the storage battery 50 in the present use state on the basis of the deterioration rate influence degrees (Im, Tm, Sm, and Dm), the base deterioration rate Vb, and the deterioration rate influence degrees (Imb, Tmb, Smb, and Dmb) under the operation condition (Step S6). The present deterioration rate Vn is calculated on the basis of the following expression (5). In the expression (5), the base deterioration rate Vb of the storage battery 50 is a deterioration rate of the storage battery 50 under the operation condition, and is stored in advance in the parameter storage unit 13A as the parameter. In the expression (5), the deterioration rate influence degrees (Imb, Tmb, Smb, and Dmb) are calculated in advance from the operation condition of the base deterioration rate Vb on the basis of the load of the storage battery 50 and the actual measurement data of the state of health of the storage battery 50, and are stored in advance in the parameter storage unit 13A as the parameters.

$${V}_{n} [ \% / \sqrt{h} ] = {V}_{b} \times [ \frac{\text{?}}{{I}_{mb}} ] \times [ \frac{{T}_{m}}{{T}_{mb}} ] \times [ \frac{{S}_{m}}{{S}_{mb}} ] \times [ \frac{{D}_{m}}{{D}_{mb}} ] \qquad ( 5 )$$

$$\text{?} \text{indicates text missing or illegible when filed}$$

After calculating the present deterioration rate Vn, the state of health calculation unit 13D calculates previous root time Hb indicating the root time of the storage battery 50 to the previous SOH on the basis of the present deterioration rate Vn and the previous SOH indicating the SOH calculated in the previous use state (Step S7). In the embodiment, the root time refers to a root value (square root) of the use time h. In a case where the previous SOH is an SOHb, the previous root time Hb is calculated on the basis of the following expression (6).

$${H}_{b} = \frac{100 - {SOH}_{b}}{{V}_{n}} \qquad ( 6 )$$

After calculating the previous root time Hb, the state of health calculation unit 13D calculates a present SOH indicating the SOH of the storage battery 50 in the present use state on the basis of the previous root time Hb, the present deterioration rate Vn, and present root time Hn indicating the root time of the present use state (Step S8). In a case where the present root time is Hn and the present SOH is an SOHn, the present SOH is calculated on the basis of the following expression (7).

$$SO \text{?} = 100 - \text{?} \times \sqrt{{H}_{b}^{2} + {H}_{n}^{2}} \qquad ( 7 )$$

$$\text{?} \text{indicates text missing or illegible when filed}$$

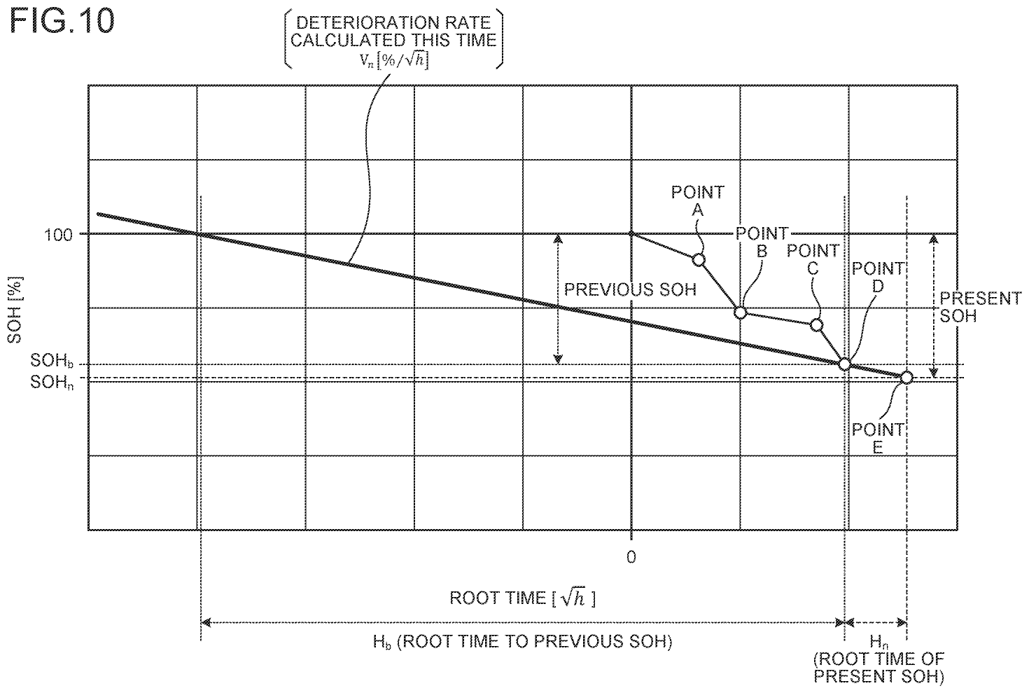

FIG. 10 is a view for describing a calculation method of the state of health of the storage battery 50 according to the embodiment. In the graph illustrated in FIG. 10, a horizontal axis represents root time, and a vertical axis represents the SOH. The previous SOH has already been calculated in the previous use state of the storage battery 50, and is stored in an SOH storage unit (not illustrated) of the master controller 13. The present deterioration rate Vn calculated in Step S6 indicates a slope of a line illustrated in FIG. 10. Note that in FIG. 10, each of a “point A”, a “point B”, a “point C”, and a “point D” indicates actual measurement data of the SOH calculated in each of a plurality of past use states. The SOH at the “point D” is the previous SOH.

The previous root time Hb is a root time required to reach the SOH in a case where it is assumed that the storage battery 50 has been deteriorated at the present deterioration rate Vn in the past. The present root time Hn is calculated on the basis of the measurement result of the timer. As illustrated in FIG. 10, the state of health calculation unit 13D can create a line that passes through the point D and has the slope of Vn, and calculate the present SOH indicated by the “point E” on the basis of the previous root time Hb, the present root time Hn, and the present deterioration rate Vn.

The state of health calculation unit 13 calculates ΔSOH indicating a change amount of the SOH between a start time point and an end time point of the present use state (Step S9). ΔSOH is calculated on the basis of the following expression (8).

$$Δ SOH = SO \text{?} - SO \text{?} \qquad ( 8 )$$

$$\text{?} \text{indicates text missing or illegible when filed}$$

ΔSOH indicates the state of health of only the present use state. The state of health calculation unit 13D can also calculate ΔSOH indicating an individual state of health in each of the plurality of use states. The above-described present SOH indicates a total state of health after the plurality of use states. The present SOH corresponds to the sum of a plurality of pieces of ΔSOH. The state of health calculation unit 13D can calculate the present SOH indicating the present total state of health after the plurality of use states.

### [Computer System]

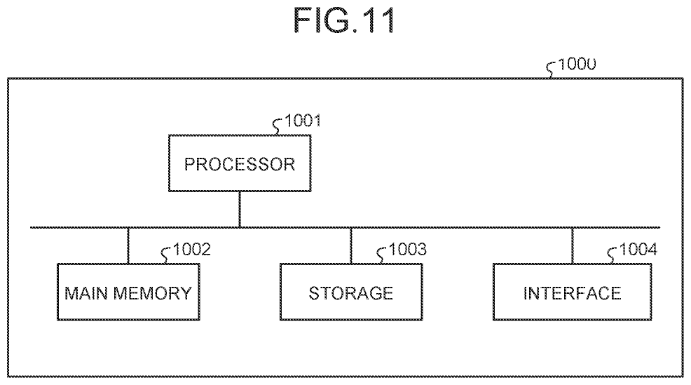

FIG. 11 is a block diagram 11 illustrating a computer system 1000 according to the embodiment. Each of the management controller 11, the power supply controller 12, and the master controller 13 described above includes the computer system 1000. The computer system 1000 includes a processor 1001 such as a central processing unit (CPU), a main memory 1002 including a non-volatile memory such as a read only memory (ROM) and a volatile memory such as a random access memory (RAM), a storage 1003, and an interface 1004 including an input/output circuit. A function of each of the management controller 11, the power supply controller 12, and the master controller 13 described above is stored in the storage 1003 as a computer program. The processor 1001 reads the computer program from the storage 1003, develops the computer program in the main memory 1002, and executes the above-described processing according to the program. Note that the computer program may be distributed to the computer system 1000 through a network.

The computer program or the computer system 1000 can execute specifying the use state of the storage battery 50 mounted on the work machine 1 and calculating the state of health of the storage battery 50 in each of the plurality of use states according to the above-described embodiment.

As described above, the state of health estimation system 200 of the storage battery 50 according to the embodiment includes the use state specification unit 13B that specifies the use state of the storage battery 50 mounted on the work machine 1, and the state of health calculation unit 13D that calculates the state of health of the storage battery 50 in each of the plurality of use states (ΔSOH). ΔSOH includes at least one of the state of health in the charged state, the state of health in the discharging state, or the state of health in the suspended state. The state of health of the storage battery 50 may change depending on the use states of the storage battery 50. In the embodiment, the state of health calculation unit 13D estimates the state of health in consideration of the use states of the storage battery 50. As a result, the state of health calculation unit 13D can accurately estimate the present total state of health (present SOH) after the plurality of use states.

In the above-described embodiment, it is assumed that the work machine 1 is a battery forklift. The work machine 1 may be a battery excavator. In addition, the work machine 1 is not limited to the battery forklift or the battery excavator, and may be any work machine using the storage battery 50 as a power source.

1. A system of estimating a state of health of a storage battery, the system comprising:
a controller, the controller being configured to
specify a use state of the storage battery, and
calculate the state of health of the storage battery in each of a plurality of use states.

2. The system according to claim 1, wherein
the plurality of use states include a charged state, a discharging state, and a suspended state.

3. The system according to claim 1, wherein
the controller is further configured to
store a parameter indicating a characteristic value related to a deterioration rate of the storage battery,
acquire an operation condition of the storage battery, and
calculate the state of health on a basis of the parameter and the operation condition.

4. The system according to claim 3, wherein
the controller is configured to store correlation data indicating a relationship between the operation condition of the storage battery and the deterioration rate of the storage battery, and
the parameter is derived from the correlation data.

5. The system according to claim 4, wherein
the controller is further configured to
calculate, on a basis of the parameter and the operation condition, a deterioration rate influence degree indicating a deterioration rate obtained by assignment of the operation condition into the correlation data,
calculate a present deterioration rate indicating the deterioration rate of the storage battery in a present use state on a basis of the operation condition and the deterioration rate influence degree,
calculate, on a basis of the present deterioration rate and a previous SOH indicating the state of health calculated in a previous use state, a previous root time indicating a root value of use time of the storage battery to the SOH, and
calculate a present SOH indicating the state of health of the storage battery in the present use state on a basis of the previous root time, the present deterioration rate, and a present root time indicating a root time of the present use state.

6. The system according to claim 3, wherein
the operation condition includes an average current, an average temperature, an average state of charge, and a state of charge change amount of the storage battery in the use time in each of the plurality of use states.

7. A work machine comprising:
the system according to claim 1.

8. A method of estimating a state of health of a storage battery, the method comprising:
specifying a use state of the storage battery; and
calculating the state of health of the storage battery in each of a plurality of the use states.
